(19) United States
(12) Patent Application Publication
(10) Pub. No.: US 2008/0260963 A1
(43) Pub. Date: Oct. 23, 2008

(54) APPARATUS AND METHOD FOR PRE AND POST TREATMENT OF ATOMIC LAYER DEPOSITION

(76) Inventors: Hyungsuk Alexander Yoon, San Jose, CA (US); Mikhail Korolik, San Jose, CA (US); Fritz C. Redeker, Fremont, CA (US); John M. Boyd, Woodlawn (CA); Yezdi Dordi, Palo Alto, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 11/736,514

(22) Filed: Apr. 17, 2007

(51) Int. Cl. C23C 14/02; B05B 15/00

(52) U.S. Cl. 427/534; 118/723 I

(57) ABSTRACT

The embodiments fill the needs of systems and processes that perform substrate surface treatment to provide homogenous, clean, and sometimes activated surface in order to provide good adhesion between layers to improve metal migration and void propagation. In an exemplary embodiment, a proximity head for treating a substrate surface is provided. The proximity head is configured to dispense a treatment gas to treat an active process region of a substrate surface under the proximity head. The proximity head covers the action process region of the substrate surface and the proximity head includes at least one vacuum channel to pull excess treatment gas from a reaction volume between the proximity head and the substrate. The proximity head has an excitation chamber to excite the treatment gas before the treatment gas being dispensed on the active process region portion of the substrate surface.

### CROSS REFERENCE TO RELATED APPLICATION

This application is related to U.S. patent application Ser. No. ______ (Attorney Docket No. LAM2P603), entitled “Apparatus and Method for Atomic Layer Deposition,” U.S. patent application Ser. No. ______ (Attorney Docket No. LAM2P605), entitled “Apparatus and Method for Integrated Surface Treatment and Film Deposition,” and U.S. patent application Ser. No. ______ (Attorney Docket No. LAM2P606), entitled “Apparatus and Method for Integrated Surface Treatment and Deposition for Copper Interconnect,” all of which are filed on the same day as the instant application. The disclosure of these related applications is incorporated herein by reference in their entireties for all purposes.

This application is also related to U.S. patent application Ser. No. 11/173,729 (Attorney Docket No. LAM2P508), entitled “A Method and Apparatus for Atomic Layer Deposition (ALD) in a Proximity System” filed on Jun. 30, 2005, which is incorporated herein by reference in its entirety.

### BACKGROUND

In the fabrication of semiconductor devices such as integrated circuits, memory cells, and the like, a series of manufacturing operations are performed to define features on semiconductor wafers. The semiconductor wafers include integrated circuit devices in the form of multi-level structures defined on a silicon substrate. At a substrate level, transistor devices with diffusion regions are formed. In subsequent levels, interconnect metallization lines are patterned and electrically connected to the transistor devices to define a desired integrated circuit device. Also, patterned conductive layers are insulated from other conductive layers by dielectric materials.

Reliably producing sub-micron and smaller features is one of the key technologies for the next generation of very large scale integration (VLSI) and ultra large scale integration (ULSI) of semiconductor devices. However, the shrinking dimensions of interconnect in VLSI and ULSI technologies have placed additional demands on the processing capabilities. As circuit densities increase, the widths of vias, contacts and other features, as well as the dielectric materials between them, decrease to sub-micron dimensions (e.g., less than 0.20 micrometers or less), whereas the thickness of the dielectric layers remains substantially constant, with the result that the aspect ratios for the features, i.e., their height divided by width, increase. Many traditional deposition processes have difficulty achieving substantially void-free and seam-free filling of sub-micron structures where the aspect ratio exceeds 4:1.

Currently, copper and its alloys have become the metals of choice for sub-micron interconnect technology due to its lower resistivity. One problem with the use of copper is that copper diffuses into silicon, silicon dioxide, and other dielectric materials, which may compromise the integrity of devices. Therefore, conformal barrier layers become increasingly important to prevent copper diffusion. Copper might not adhere well to the barrier layer; therefore, a liner layer might need to be deposited between the barrier layer and copper. Conformal deposition of the liner layer is also important to provide good step coverage to assist copper adhesion and/or deposition.

Conformal deposition of the barrier layer on interconnect features by deposition methods, such as atomic layer deposition (ALD), needs to occur on clean surfaces to ensure good adhesion between the barrier layer and/or liner layer, and the material(s) the barrier layer deposited upon. Surface impurity can become a source of defects during the heating cycles of the substrate processing. Pre-treatment can be used to remove unwanted compounds from the substrate surface prior to barrier deposition. In addition, deposition by ALD might need surface pre-treatment to make the substrate surface easier to bond with the deposition precursor to improve the quality of barrier layer deposition.

Electro-migration (EM) is a well-known reliability problem for metal interconnects, caused by electrons pushing and moving metal atoms in the direction of current flow at a rate determined by the current density. EM in copper lines is a surface phenomenon. It can occur wherever the copper is free to move, typically at an interface where there is poor adhesion between the copper and another material, such as at the copper/barrier or copper/liner interface. The quality and conformality of the barrier layer and/or liner layer can certainly affect the EM performance of copper interconnect. It is desirable to perform the ALD barrier and liner layer deposition right after the surface pre-treatment, since the pre-treated surface might be altered if the surface is exposed to oxygen or other contaminants for a period of time.

In view of the foregoing, there is a need for apparatus and methods that perform substrate surface treatment to provide a homogenous, clean, and sometimes activated surface in order to provide good adhesion between material layers to improve metal migration and void propagation.

### SUMMARY

Broadly speaking, the embodiments fill the needs of apparatus and methods that perform substrate surface treatment to provide homogenous, clean, and sometimes activated surface in order to provide good adhesion between layers to improve metal migration and void propagation. It should be appreciated that the present invention can be implemented in numerous ways, including as a solution, a method, a process, an apparatus, or a system. Several inventive embodiments of the present invention are described below.

In one embodiment, an apparatus for treating a surface of a substrate is provided. The apparatus includes a substrate support configured to support the substrate. The apparatus also includes a proximity head configured to dispense a treatment gas to treat an active process region of a substrate surface under the proximity head. The proximity head covers the action process region of the substrate surface and the proximity head includes at least one vacuum channel to pull excess treatment gas from a reaction volume between the proximity head and the substrate. The proximity head has an excitation chamber to excite the treatment gas before the treatment gas being dispensed on the active process region portion of the substrate surface.

In another embodiment, a proximity head for treating a substrate surface is provided. The proximity head is configured to dispense a treatment gas to treat an active process region of a substrate surface under the proximity head. The proximity head covers the action process region of the substrate surface and the proximity head includes at least one vacuum channel to pull excess treatment gas from a reaction volume between the proximity head and the substrate. The proximity head has an excitation chamber to excite the treatment gas before the treatment gas being dispensed on the active process region portion of the substrate surface.

In yet another embodiment, a method of treatment a substrate surface is provided. The method includes moving a proximity head for surface treatment above a substrate. The proximity head has at least one gas channel configured to dispense a treatment gas on a region of the substrate surface. The proximity head has at least one vacuum channel used to vacuum excess treatment gas from a reaction volume underneath the proximity head. The proximity head for surface treatment covers the region of the substrate surface. The method also includes exciting the treatment gas in an excitation chamber of the proximity head before the treatment gas is dispensed on the region of the substrate surface. In addition, the method includes dispensing the excited treatment gas on the region of the substrate surface to treat the substrate surface.

### BRIEF DESCRIPTION OF THE DRAWINGS

The present invention will be readily understood by the following detailed description in conjunction with the accompanying drawings, and like reference numerals designate like structural elements.

FIG. 1A show an exemplary cross section of an interconnect structure prior to barrier layer deposition, in accordance of an embodiment of the current invention.

FIG. 1B show an exemplary cross section of an interconnect structure after deposition of barrier layer deposition and copper, in accordance of an embodiment of the current invention.

FIG. 2 shows an exemplary ALD deposition cycle.

FIG. 3 shows a cross-sectional diagram of an ALD film grown with limited growth sites in the beginning of ALD deposition.

FIG. 4 shows a schematic diagram of a chamber with a surface treatment proximity head, in accordance with an embodiment of the current invention.

FIG. 5A shows a schematic diagram of a proximity head for surface treatment, in accordance with an embodiment of the current invention.

FIG. 5B shows a top view of a proximity head for surface treatment over a substrate, in accordance with an embodiment of the current invention.

FIG. 5C shows a top view of a proximity head for surface treatment over a substrate, in accordance with another embodiment of the current invention.

FIG. 5D shows a top view of a proximity head for surface treatment over a substrate, in accordance with yet another embodiment of the current invention.

FIG. 5E shows a bottom view of a proximity head for surface treatment, in accordance with an embodiment of the current invention.

FIG. 5F shows a bottom view of a proximity head for surface treatment, in accordance with another embodiment of the current invention.

FIG. 5G shows a schematic cross-sectional view of a proximity head for surface treatment below a substrate, in accordance with one embodiment of the current invention.

FIG. 5H shows a schematic diagram of a proximity head for surface treatment, in accordance with an embodiment of the current invention.

FIG. 5I shows a schematic diagram of a proximity head for surface treatment, in accordance with another embodiment of the current invention.

FIG. 5J shows a schematic diagram of a proximity head for surface treatment coupled to an RF power source over a substrate and a grounded substrate support, in accordance with an embodiment of the current invention.

FIG. 5K shows a schematic diagram of a grounded proximity head for surface treatment over a substrate and a substrate support coupled to an RF power source, in accordance with an embodiment of the current invention.

FIG. 6A show s plurality of proximity heads for surface treatment and deposition over a substrate, in accordance with an embodiment of the current invention.

FIG. 6B show s plurality of proximity heads for surface treatment and deposition over a substrate, in accordance with another embodiment of the current invention.

FIG. 6C shows a proximity head for CVD over a substrate, in accordance with one embodiment of the current invention.

FIG. 6D show s plurality of proximity heads for surface treatment and deposition over a substrate, in accordance with yet another embodiment of the current invention.

FIG. 7A shows a process flow of surface treatment using a proximity head, in accordance with an embodiment of the current invention.

### DETAILED DESCRIPTION OF THE EXEMPLARY EMBODIMENTS

Several exemplary embodiments for apparatus and methods for substrate surface treatment prior to and after deposition are detailed. Substrate pre-treatment prior to film deposition can remove surface contaminants and/or activate surface for deposition. Substrate post-treatment after film deposition can remove surface contaminants and/or prepare the substrate surface for deposition of another film. The pre-treatment and post-treatment are performed with proximity heads, which can be integrated in one processing chamber. In addition, pre-treatment and post-treatment using proximity heads can also be integrated with an atomic layer deposition (ALD) proximity head to complete the deposition and treatment in one chamber.

It should be appreciated that the present invention can be implemented in numerous ways, including a process, a method, an apparatus, or a system. Several inventive embodiments of the present invention are described below. It will be apparent to those skilled in the art that the present invention may be practiced without some or all of the specific details set forth herein.

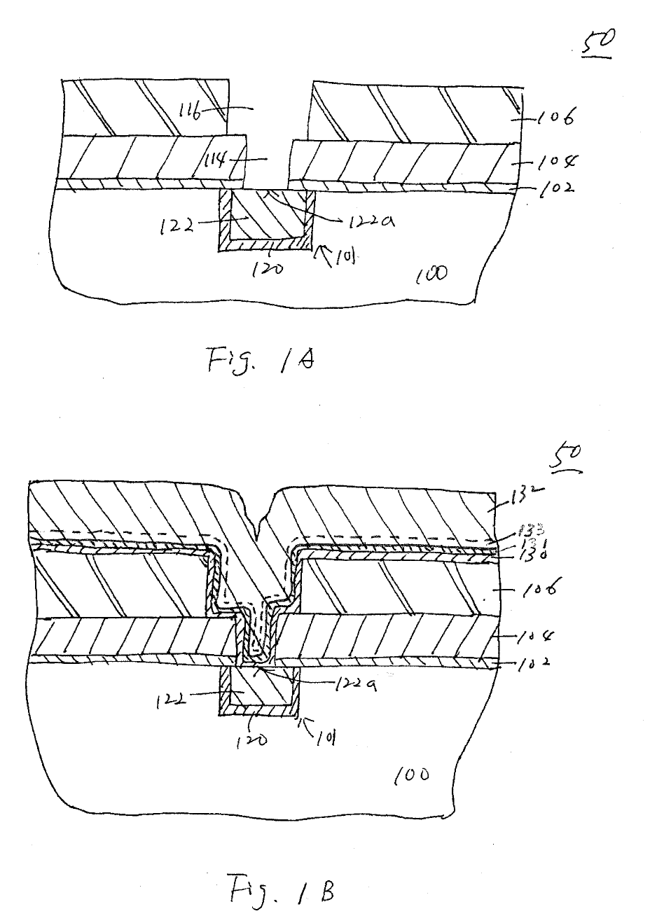

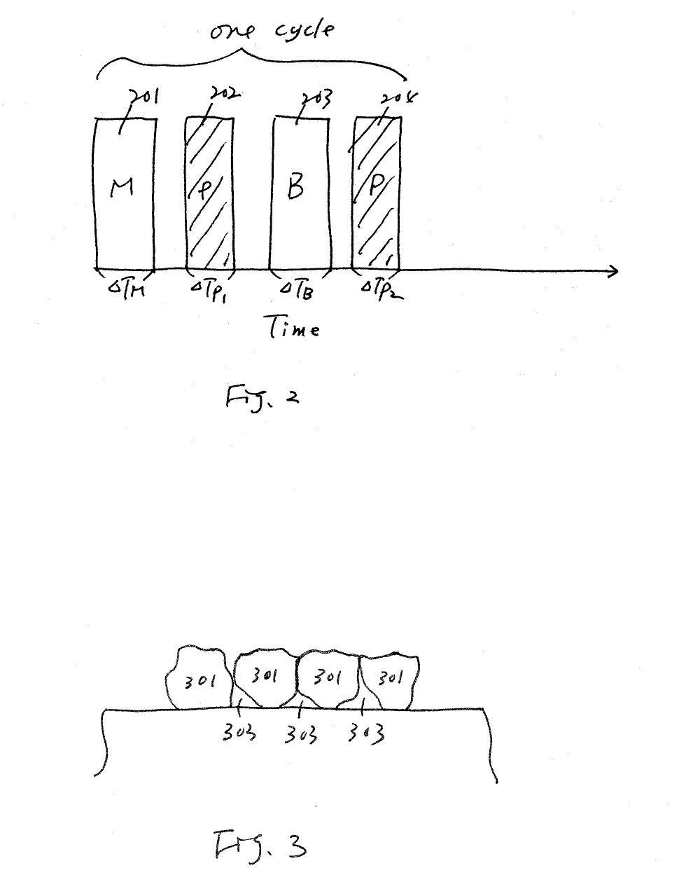

FIG. 1A shows an exemplary cross-section of an interconnect structure(s) after being patterned by using a dual damascene process sequence. The interconnect structure(s) is on a substrate 50 and has a dielectric layer 100, which was previously fabricated to form a metallization line 101 therein. The metallization line is typically fabricated by etching a trench into the dielectric 100 and then filling the trench with a conductive material, such as copper.

In the trench, there is a barrier layer 120, used to prevent the copper material 122, from diffusing into the dielectric 100. The barrier layer 120 can be made of PVD tantalum nitride (TaN), PVD tantalum (Ta), ALD TaN, or a combination of these films. Other barrier layer materials can also be used. Alternatively, a liner layer can be deposited between the barrier layer 120 and the copper material 122 to increase the adhesion between the copper material 122 and the barrier layer 120. Another barrier layer 102 is deposited over the planarized copper material 122 to protect the copper material 122 from premature oxidation when via holes 114 are etched through overlying dielectric materials 104, 106 to the barrier layer 102. The barrier layer 102 is also configured to function as a selective etch stop and a copper diffusion barrier. Exemplary barrier layer 102 materials include silicon nitride (SiN) or silicon carbide (SiC).

A via dielectric layer 104 is deposited over the barrier layer 102. The via dielectric layer 104 can be made of a material with a low dielectric constant. Over the via dielectric layer 104 is a trench dielectric layer 106. The trench dielectric layer 106 may be a low K dielectric material, which can be a material same as or different from layer 104. In one embodiment, both the via and trench dielectric layers are made of the same material, and deposited at the same time to form a continuous film. After the trench dielectric layer 106 is deposited, the substrate 50 that holds the structure(s) undergoes patterning and etching processes to form the via holes 114 and trenches 116 by known art.

FIG. 1B shows that after the formation of via holes 114 and trenches 116, a barrier layer 130, an optional liner layer 131, and a copper layer 132 are deposited to line and fill the via holes 114 and the trenches 116. The barrier layer 130 can be made materials, such as tantalum nitride (TaN), tantalum (Ta), Ruthenium (Ru), or a hybrid combination of these films. Barrier layer materials may be other refractory metal compound including but not limited to titanium (Ti), titanium nitride (TiN), tungsten (W), zirconium (Zr), hafnium (Hf), molybdenum (Mo), niobium (Nb), vanadium (V), and chromium (Cr), among others.

The optional liner layer 131 can be made materials, such as tantalum (Ta), and Ruthenium (Ru). Liner layer materials may be other refractory metal compound including but not limited to titanium (Ti), titanium nitride (TiN), tungsten (W), zirconium (Zr), hafnium (Hf), molybdenum (Mo), niobium (Nb), vanadium (V), and chromium (Cr), among others. While these are the commonly considered materials, other barrier layer and liner layer materials can also be used. A copper film 132 is then deposited to fill the via holes 114 and the trenches 116. A copper seed layer 133 can be deposited prior to the gap-filling copper film 132 is deposited.

As discussed above, before depositing a metallic barrier layer 130, the substrate surface can have residual contaminants left from etching the dielectric layers 104, 106 and the barrier layer 102 to allow the metallic barrier layer 130 to be in contact with the copper material 122. A cleaning process, such as Ar sputtering, can be used to remove surface contaminant. Also as discussed above, conformal deposition of metallic barrier layer 130 by ALD might need surface pre-treatment to make the substrate surface easier to bond with the deposition precursor. The reason is described below.

Atomic layer deposition (ALD) is known to produce thin film with good step coverage. ALD is typically accomplished by using multiple pulses, such as two pulses, of reactants with gas purge in between, as shown in FIG. 2. For metallic barrier deposition, a pulse of barrier-metal-containing reactant (M) 201 is delivered to the substrate surface, followed by a pulse of purging gas (P) 202. The pulse of barrier-metal-containing reactant 201 delivered to the substrate surface to form a monolayer of barrier metal, such as Ta, on the substrate surface. In one embodiment, the pulse of purging gas is a plasma enhanced (or plasma assisted) gas. The barrier metal, such as Ta, bonds to the substrate surface, which can be made of a dielectric material, such as low-k materials 104, 106 of FIG. 1A, and/or a conductive material, such as copper material 122 of FIG. 1A. The purge gas 202 removes the excess barrier-metal-containing reactant 201 from the substrate surface.

Following the pulse of the purging gas 202, a pulse of reactant (B) 203 is delivered to the substrate surface. If the barrier material contains nitrogen, such as TaN, the reactant (B) 203 is likely to contain nitrogen. The reactant (B) 203 can be nitrogen-containing gas to form TaN with the Ta on the substrate. Examples of reactant (B) 203 include ammonia (NH₃), N₂, and NO. Other N-containing precursors gases may be used including but not limited to NₓH_{y} for x and y integers (e.g., N₂H₄), N₂ plasma source, NH₂N(CH₃)₂, among others. If the barrier material contains little or no nitrogen, the reactant (B) 203 can be a hydrogen-containing reducing gas, such as H₂. H₂ is a reducing gas that reacts with the ligand bounding with the barrier-metal in reactant M 201 to terminate the film deposition. Following pulse 203 is a pulse of purging gas 204. Reactants M, B, and purge gas P can be plasma enhanced or thermally excited. In one embodiment, the pulse of reactant (B) 203 is a plasma-enhanced (or plasma-assisted).

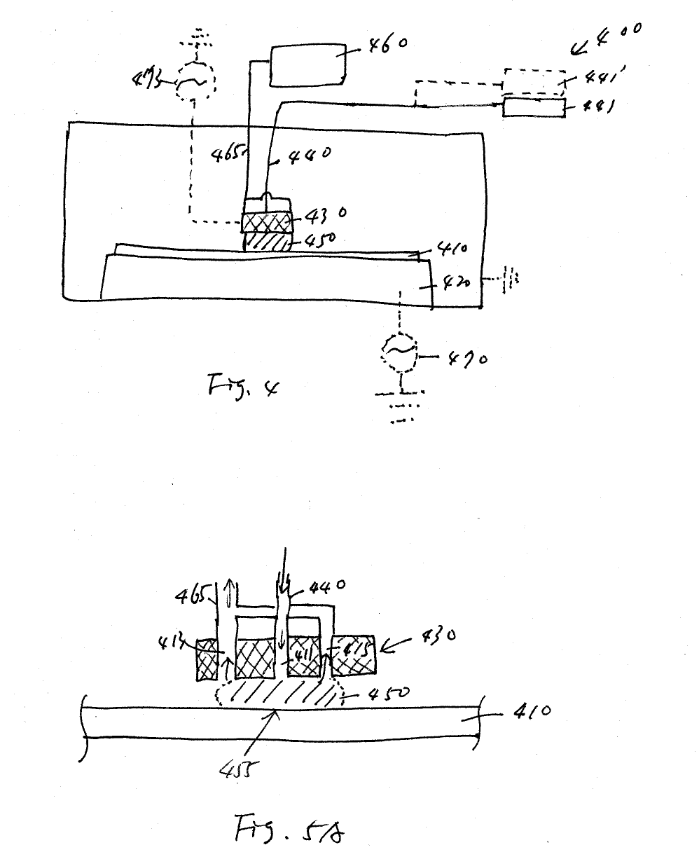

However, in some situations, the substrate surface does not possess ample bonding sites for all the potential locations on the surface. Accordingly, the barrier-metal-containing reactant M (or precursor) bonding to the surface can result in the formation of islands and grains which are sufficiently far apart to form poor quality ALD film. FIG. 3 shows an ALD film with islands 301 that are grown with limited growth sites in the beginning of ALD deposition. Between the islands 301, there are voids 303 along the surface of the substrate. Substrate surface, such as SiO2 or low-k material, can be quite inert and not easy to bond with for barrier metal in the barrier-metal-containing reactant M. Surface treatment by OH, O, or O radical exposure can efficiently insert HOH into the SiOSi to generate 2 Si—OH surface species that are highly reactive with the barrier-metal-containing reactant M. The introduction of the pre-treatment plasma into the processing chamber containing the substrate can result in the formation of surface species at various desired bonding sites. In order to grow continuous interfaces and films, one embodiment of the present invention is to pre-treat the surface of the substrate prior to ALD in order to make the surface more susceptible to ALD, due to more deposition sites.

After barrier layer and/or liner layer is deposited on the substrate surface, the surface can be post-treated to remove any surface contaminant or to reduce impurities in the film, or to density the film. In addition, post-treatment can enhance nucleation of copper seed layer deposited by an electroless process in a similar mechanism described above. Copper seed layer with enhanced nucleation has better film quality and results in better reliability (such as EM performance).

Surface treatment can be a plasma process. The plasma can be generated in the process chamber, which is called “direct plasma”, or can be generated in a remote reactor, which is called “remote plasma.” Examples of gases for generating plasma for the pre-treatment or post-treatment include, but not limited to, H₂, NH₃, NF₃, NH₄F, O₂, and N₂. Surface treatment can also performed with a thermally excited gas. Examples of gases for thermally excited gas for the pre-treatment or post-treatment include, but not limited to, H₂, NH₃, NF₃, NH₄F, O₂, and N₂. The thermal excitation can be performed with hot filament. Alternatively, surface treatment can also performed with a laser or ultra-violet (UV) excited gas. Examples of gases for laser or UV excited gas for the pre-treatment or post-treatment include, but not limited to, H₂, NH₃, NF₃, NH₄F, O₂, and N₂.

FIG. 4 shows a schematic diagram of a chamber 400 for substrate surface treatment with a proximity head 440. In chamber 400, there is a substrate 410 disposed on a substrate support 420. The proximity head 440 is supported above substrate 410. Between the proximity head 430 and the substrate 410, there is a reaction volume 450. Since the proximity head 440 only covers a portion of the substrate surface, the reaction volume 450 is much smaller than conventional surface treatment that applies to the entire substrate surface.

A gas inlet 440 and a vacuum line 465 are coupled to the proximity head 430. The other end of the vacuum line 465 is a pump 460. There is also a vacuum pump (not shown) coupled to the process chamber to maintain the chamber pressure.

The gas inlet 440 supplies reactant gas to process chamber 400. The excess treatment gas is pumped away from the from the reaction volume 450 by the vacuum line 465. The gas inlet 440 can be coupled to a container 441 that stores a treatment gas, such as H₂. The treatment gas can be diluted with an inert gas. As described above, the treatment gas can be plasma assisted. In one embodiment, the plasmarized treatment gas is supplied by a reactor 441′ that plasmarizes the treatment gas. Alternatively, the substrate support 420 can be coupled to a radio frequency (RF) generator to generate plasma to plasmarize treatment gas when treatment gas is dispensed into the reaction volume 450, instead of supplying plasmarized treatment from reactor 441′. Another alternative is to couple an RF generator 473 to the proximity head 430 to generate plasma. The inert gas can be used to sustain chamber pressure or to sustain plasma.

There could be a heater (not shown) and/or a cooler coupled to, or embedded in, the substrate support 420 to maintain the substrate temperature. Other parts of the chamber could also be heated or cooled to maintain process temperature.

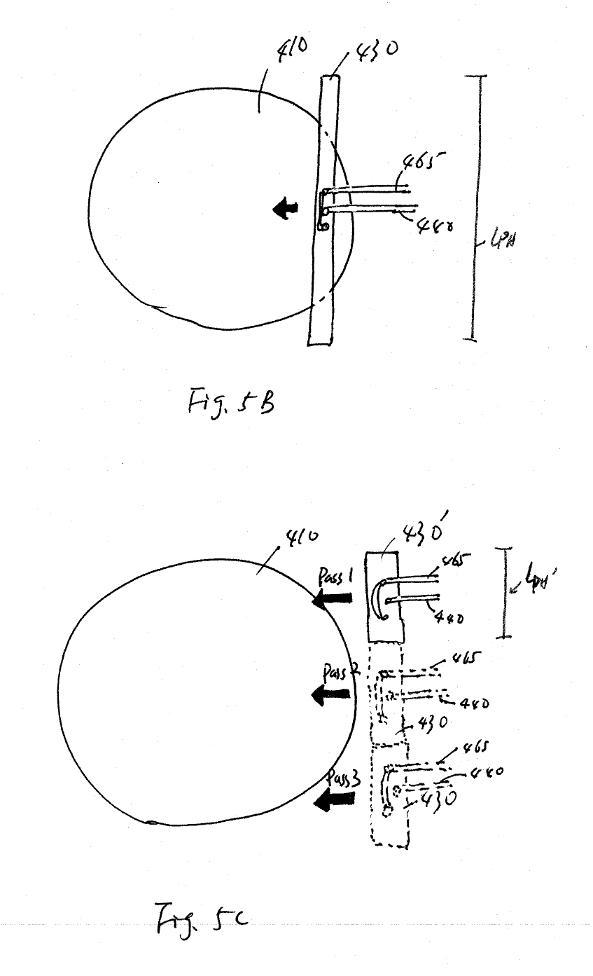

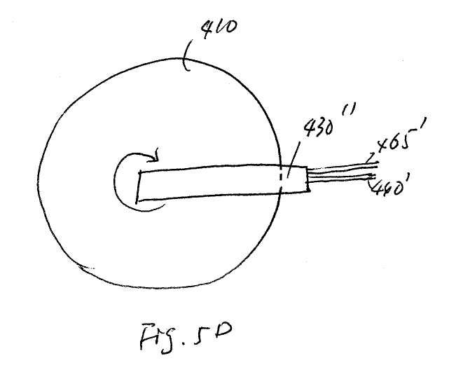

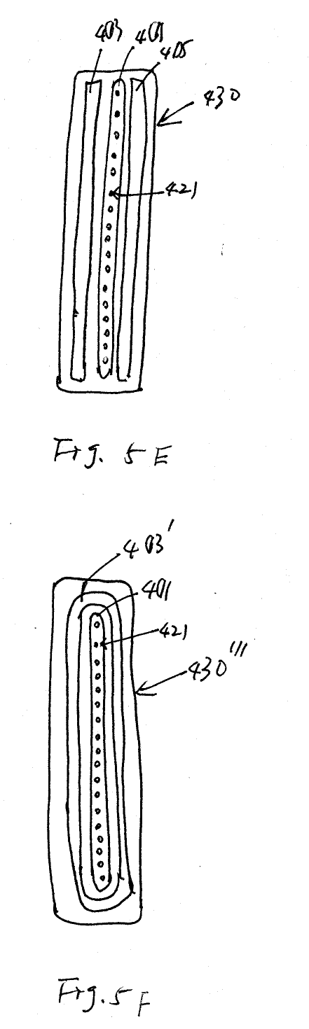

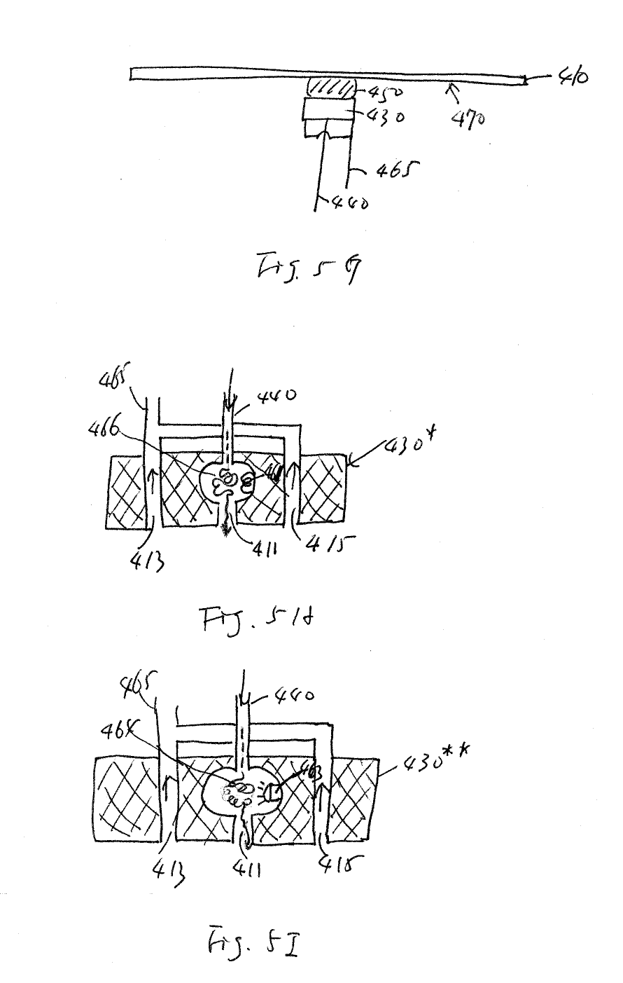

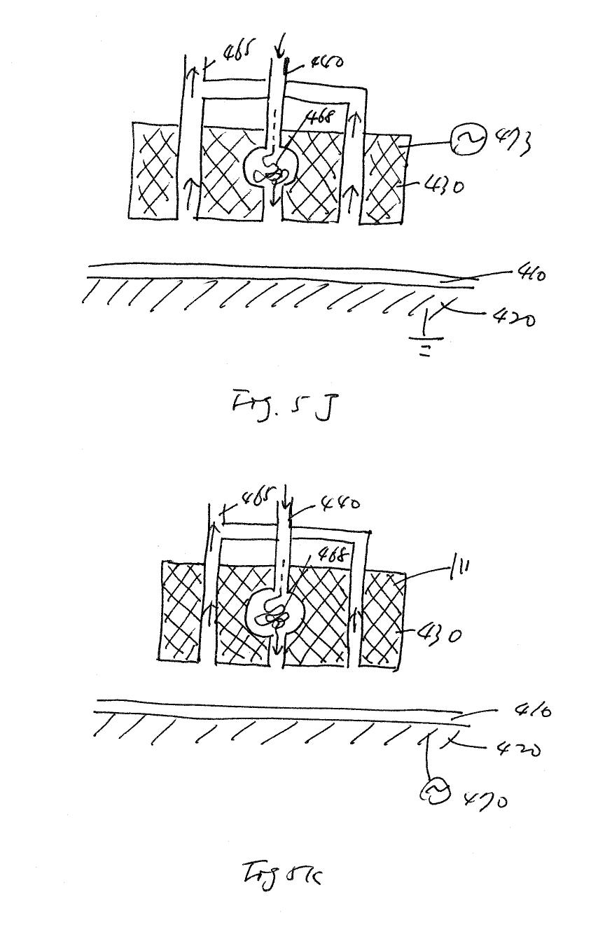

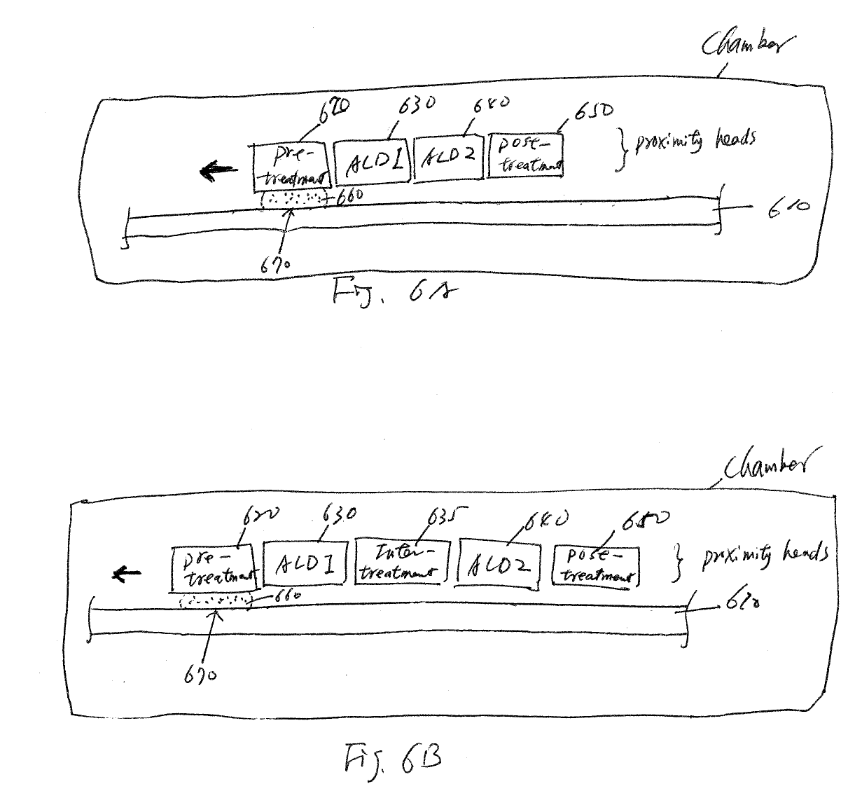

FIG. 5A shows one embodiment of a proximity head 410 disposed above substrate 410, with a reaction volume 450 between the proximity head 410 and substrate 410. The substrate surface under the reaction volume 450 is an active process region 455. The proximity head 410 has one or more gas channels 411 that supply treatment gas. On both sides of the gas channel 411, there are vacuum channels 413, 415 pumping excess treatment gas(es) from the reaction volume 450. Gas channel 411 is coupled the container of the treatment gas. When treatment gas is injected form the gas channel 411 to the substrate surface, the excess amount of gas is pumped away from the substrate surface by the vacuum channels 413, 415, which limits the reaction volume to be substantially below the proximity head 430.

FIG. 5B shows a schematic top view of an embodiment of proximity head 430 of FIG. 4 and FIG. 5A on top of a substrate 410. Proximity head 430 moves across the substrate surface. In this embodiment, the length of the proximity head LPH is equal to or greater than the diameter of the substrate. The reaction volume under the proximity covers the substrate surface underneath. By moving the proximity head across the substrate once, the entire substrate surface is treated with the treatment gas, which can be excited by plasma, thermally, by UV, or by laser. In another embodiment, the substrate 410 is moved under the proximity head 430. In yet another embodiment, both the proximity head 430 and the substrate 410 move, but in opposite directions to cross each other. The amount of surface treatment the substrate receives can be controlled by the speed the proximity head 430 move across the substrate 410.

Alternatively, the length of the proximity head LPH can be shorter than the diameter of the substrate. Multiple passes of the proximity head 430′ across the substrate is needed to deposit a thin barrier or liner layer on the substrate surface. FIG. 5C shows a proximity head 430′ with the length of the proximity head L_{PH′} shorter than the diameter of the substrate. After the proximity head 430′ move across the substrate surface in pass 1, the proximity head 430′ can move downward to move across the substrate in pass 2 and pass 3. At the end of pass 3, the entire substrate surface is deposited with a thin layer of the barrier or liner film.

FIG. 5D shows another embodiment with a proximity head 430″ rotating around the surface of substrate 410. In this embodiment, the treatment gas is supplied to a gas inlet 440′ that is attached to the end of the proximity head 430. The vacuum line 465′ is also coupled to the end of the proximity head 430″.

FIG. 5E show an embodiment of a bottom view of the proximity head 430 of FIG. 5A. The proximity head 430 has a gas injection head 401, coupled to gas channel 411 with a plurality of gas injection holes 421. The arrangement and shapes of gas injection holes 421 shown in FIG. 5E are merely examples. Other arrangement of injection holes and shapes of injection holes can also be used. In one embodiment, the injection head 410 has only one narrow slit (not shown), not injection holes. Alternatively, For example, there could be two or more rows of injection holes, instead of one. The injection holes can be staggered or can be side by side. The shapes of the injection holes can be round, square, hexagonal, or other shapes. The proximity head 430 also has vacuum heads 403, 405, coupled to the vacuum channels 413, 415 on both sides of the gas injection head 401. In this embodiment, vacuum heads, 403, 405 are two slits. Other shapes of geometries of vacuum heads can also be used. Alternatively, the slits of vacuum heads 403 and 405 are connected to become one single slit 403′ surrounding the gas injection head 401, as shown in the proximity head 430′″ in FIG. 5F.

In addition to placing a substrate under a proximity head, a substrate can also be placed above a proximity head to treat the substrate surface. FIG. 5G shows a schematic drawing of a proximity head 430 placed below a substrate 410, with an active surface 470 of the substrate 410 facing the proximity head 430. Devices are manufactured on the active surface 470. The substrate 410 is suspended above the proximity head 430 by a device (not shown). The proximity head 430 is also supported by a mechanical device (not shown).

As discussed above, the treatment gas can be thermally excited. Treatment gas can be thermally excited by a hot filament. FIG. 5H shows a proximity head 430* with a hot filament 461 in an excitation chamber 466 in the gas channel 411 to heat up the treatment gas before the treatment gas reaches the substrate surface. It was also discussed above that surface treatment can also performed with a laser or ultra-violet (UV) excited gas. FIG. 5I shows a proximity head 430** with a light source 463, which can be a laser or a UV light source, in an excitation chamber 464 to excite the treatment gas.

As discussed above, the treatment gas can be plasmarized. FIG. 5J shows a proximity head 430 with an excitation chamber 468 to plasmarize the treatment gas supplied by gas line 440. The proximity head is coupled to an RF generator 473, as described in FIG. 4. The substrate support 420 is grounded. FIG. 5K shows another embodiment with the proximity head 430 grounded and the substrate support coupled to an RF power supply 470, as described in FIG. 4.

As discussed above, a substrate to be deposited with a barrier layer and/or a liner layer might need to be pre-treated to clean the substrate surface or to prepare the substrate surface for depositing an ALD with better film quality. ALD film can also be deposited by a proximity head. Details of using a proximity head to deposit an ALD film are described in U.S. patent application Ser. No. ______ (Attorney Docket No. LAM2P603), entitled “Apparatus and Method for Atomic Layer Deposition,” which is filed on the same day as the instant application. This application is incorporated herein by reference in its entirety.

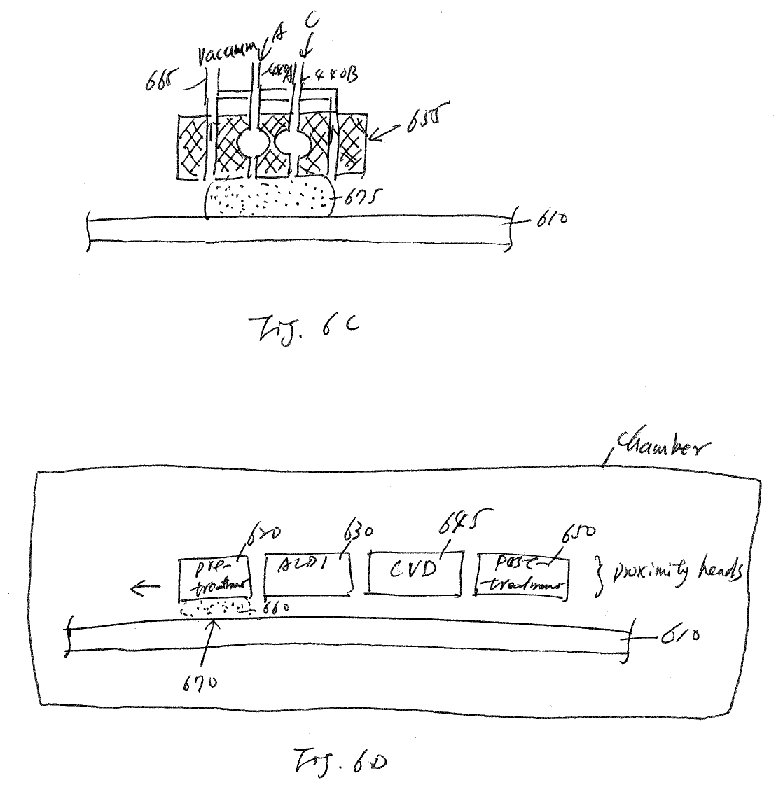

ALD proximity head(s), pre-treatment proximity head(s), and/or post-treatment proximity head(s) can be integrated in one single process chamber to complete the deposition and treatment processes. For a substrate to be deposited with a thin barrier layer, such as TaN, and a liner layer, such as Ru, the substrate can be pre-treated to clean the substrate surface or the substrate surface can be pre-treated to prepare the surface for ALD deposition, as discussed above. After the deposition, the liner layer deposition, the substrate surface can be posted-treated to prepare the surface for copper seed layer deposition. In a single and integrated deposition/treatment chamber, the substrate is pre-treated, deposited with a barrier layer and a liner layer, and post-treated. FIG. 6A shows a substrate 610 with a plurality of proximity treatment and deposition heads over the substrate 610. Pre-treatment proximity head 620 is used to pre-treat the substrate surface either to remove impurities or to prepare the substrate surface for ALD. Between the proximity head 620 and the surface of substrate 610, there is a reaction volume 660. The substrate surface below the reaction volume 660 is an active process region 670. Next to pre-treatment proximity head 620 is an ALD1 proximity head 630 used to deposit a barrier layer on the substrate. After the ALD1 proximity head 630 is an ALD2 proximity head 640 used to deposit a liner layer on the substrate. After the liner layer is deposited, the substrate is post-treated either to remove impurities or to prepare the substrate surface for copper seed layer deposition following. The post-treatment is performed by a post-treatment proximity head 650. The various proximity head moves sequentially across the substrate surface to complete treatment and deposition surface. The treatment and deposition processes can occur simultaneously or in sequence.

Many types of materials can be used to make the proximity head. The examples of these materials include, but not limited to, stainless steel, alumina (Al₂O₃), quartz, SiC, and Silicon. For treatment gases, such as H₂ and NH₃, that have short radical lifetime, quartz would be a suitable material.

The embodiment shown in FIG. 6A is only an example of integrating treatment proximity head with deposition proximity head. Other combinations are possible. For example, there could be a surface treatment after the barrier layer is deposited and before the deposition of the liner layer. FIG. 6B shows an embodiment with a surface treatment between two deposition steps. Inter-treatment proximity head 635 is inserted between ALD1 proximity head 630 and ALD2 proximity head 640.

Proximity head surface treatment chamber can be integrated with other deposition, substrate cleaning, or treatment system(s) to complete copper interconnect deposition. Details of integrating an ALD chamber using a proximity head for ALD with other deposition and treatment modules can be found in U.S. patent application Ser. No. ______ (Attorney Docket No. LAM2P606), entitled “Apparatus and Method for Integrated Surface Treatment and Deposition for Copper Interconnect,” which is filed on the same day as the instant application. The application is incorporated herein by reference in its entirety.

Proximity head for ALD also can be integrated with another proximity head for ALD or CVD, and proximity heads for pre-treatment and post-treatment in the same ALD deposition chamber to complete the barrier/liner layer deposition. Details of an integrated ALD chamber for deposition a barrier and/or liner layer is described in commonly assigned U.S. patent application Ser. No. ______ (Attorney Docket No. LAM2P605), entitled “Apparatus and Method for Integrated Surface Treatment and Film Deposition,” which is filed on the same day as the instant application. The application is incorporated herein by reference in its entirety.

The gap distance between the proximity head and the substrate for surface treatment is small is between about 5 mm to about 10 mm. The gap distance between the proximity head and the substrate during ALD changes from side to side and is less than 5 mm, such as 1 mm. The gap distance between the different proximity head and substrate surface can be different for different proximity heads in the chamber.

Proximity head can also be used to deposit thin film by methods other than ALD. For example, proximity head can be used to deposit a chemical vapor deposition (CVD) film. For copper plating, the thickness of barrier layer and/or seed layer on the substrate surface needs to be thick enough to have the sheet resistivity low enough for to copper plating. A CVD proximity head can be integrated in the chamber with ALD proximity head(s). After the conformal barrier/liner layer(s) is deposited, a less conformal CVD liner layer can be deposited to increase the thickness of the total barrier layer and liner layer(s) to lower the sheet resistivity to enable copper plating.

FIG. 6C shows a proximity head 655 that can be used to deposit a CVD (or plasma-enhanced CVD) film with reactant A and B on a substrate 610. Such a CVD proximity head can also be integrated pre-treatment proximity head, ALD proximity head, or post-treatment proximity head. Many types of combinations are possible. For example, post-treatment might not be needed after an ALD. Therefore, only pre-treatment, ALD1 proximity head, and/or ALD2 are needed. Or the combination can be pre-treatment, ALD1, CVD, and post-treatment, as shown in FIG. 6D.

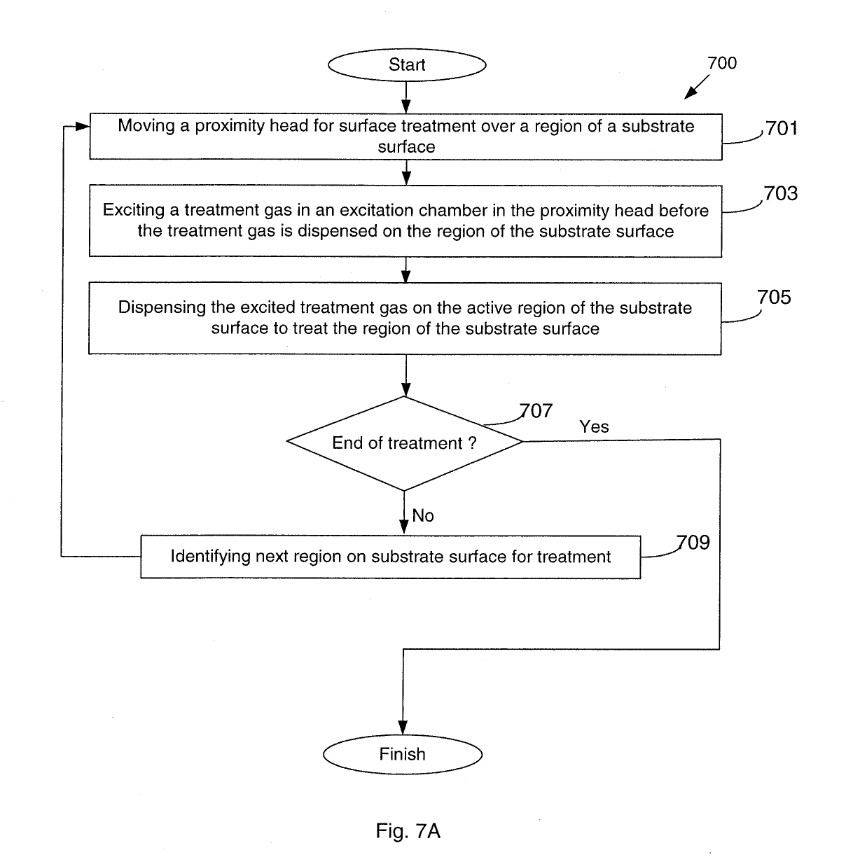

FIG. 7A shows an embodiment of a process flow 700 for treating the substrate surface. The process flow can be used to treat any type of substrate surface, and is not limited to barrier/liner layer deposition pre-treatment or post-treatment. At step 701, a proximity head for surface treatment is placed above a substrate. The proximity head is placed over a region of substrate surface that needs surface treatment. The region refers to the action process region 670 of FIG. 6A and FIG. 6B, which is under a reaction volume once the treatment gas is dispensed on the substrate surface. At step 703, the treatment gas that is used to treat the substrate surface is excited before the treatment gas is dispensed on the substrate surface to activate the treatment gas. The treatment gas can be excited thermally by a hot-filament in an excitation chamber described above. The treatment gas can also be excited by UV or by laser. In addition, the treatment gas can also be excited to be a plasma. After the treatment gas is excited, the treatment gas is dispensed on the region of the substrate surface at step 705. Afterwards, a question of whether the end of surface treatment has been reached or not is asked at step 707. If the answer is “yes”, the treatment process is finished. If the answer is “no”, the next treatment location is identifies at step 709. The process then returns to process step 701.

The surface treatment process using the proximity head can be conducted over a wide range of process conditions. In one embodiment, the process temperature range between about room temperature to about 400° C. When the surface proximity head is integrated with ALD proximity head in the same process chamber, the temperature range is between 150° C. to about 400° C. In another embodiment, the temperature range is between 250° C. to about 350° C. In one embodiment, the process pressure is between about 10 mTorr to about 10 Torr. The vacuuming of treatment gas can be performed by turbo pump capable of achieving 10⁻⁶ Torr.

There is a wafer area pressure (P_{wap}) in the reaction volume. For surface treatment, such as pre-clean, P_{wap} is in the range of about 10 mTorr to about 10 Torr. In another embodiment of ALD, P_{wap} is in the range between about 100 mTorr to about 2 Torr. Wafer area pressure P_{wap} in the reaction volume needs to be greater than chamber pressure (P_{chamber}) to control P_{wap}. Chamber pressure (P_{chamber}) needs to be at least slightly higher than the pressure of the vacuum pump that is used to control the chamber pressure.

While this invention has been described in terms of several embodiments, it will be appreciated that those skilled in the art upon reading the preceding specifications and studying the drawings will realize various alterations, additions, permutations and equivalents thereof. Therefore, it is intended that the present invention includes all such alterations, additions, permutations, and equivalents as fall within the true spirit and scope of the invention. In the claims, elements and/or steps do not imply any particular order of operation, unless explicitly stated in the claims.

What is claimed is:

1. An apparatus for treating a surface of a substrate, comprising:
a substrate support configured to support the substrate;
a proximity head configured to dispense a treatment gas to treat an active process region of a substrate surface under the proximity head, wherein the proximity head covers the action process region of the substrate surface and the proximity head includes at least one vacuum channel to pull excess treatment gas from a reaction volume between the proximity head and the substrate, the proximity head having an excitation chamber to excite the treatment gas before the treatment gas being dispensed on the active process region portion of the substrate surface.

2. The apparatus of claim 1, wherein there are two vacuum channels, one on each side of at least one gas channel to dispense the treatment gas.

3. The apparatus of claim 1, wherein there is one vacuum channel surrounding at least one gas channel to dispense the treatment gas.

4. The apparatus of claim 1, wherein the length of the proximity head is greater than the diameter of the substrate, the dispensed treatment gas covering a length equal to or greater than the diameter of the substrate.

5. The apparatus of claim 1, wherein the length of the proximity head is less than the diameter of the substrate, the dispensed treatment gas covering a length less than the diameter of the substrate.

6. The apparatus of claim 1, wherein the proximity head rotates about an axis perpendicular to the substrate.

7. The apparatus of claim 1, wherein the proximity head is configured to move to a next surface treatment location.

8. The apparatus of claim 1, wherein the dispensed treatment gas is plasmarized.

9. The apparatus of claim 1, wherein the dispensed treatment gas is plasmarized by a radio-frequency (RF) power source coupled to a substrate support or coupled to the proximity head, or in a remote plasma reactor.

10. The apparatus of claim 1, wherein the treatment gas is selected form a group consisting of H₂, NH₃, NF₃, NH₄F, O₂, and N₂.

11. The apparatus of claim 10, wherein the treatment gas is diluted by an inert gas.

12. The apparatus of claim 1, wherein the treatment gas is excited by a hot-filament, by laser, by ultra-violent (UV), or by plasma.

13. The apparatus of claim 1, wherein the proximity head is made of material selected from a group consisting of stainless steel, alumina (Al₂O₃), quartz, SiC, and Silicon.

14. A proximity head for treating a substrate surface, comprising:
the proximity head configured to dispense a treatment gas to treat an active process region of a substrate surface under the proximity head, wherein the proximity head covers the action process region of the substrate surface and the proximity head includes at least one vacuum channel to pull excess treatment gas from a reaction volume between the proximity head and the substrate, the proximity head having an excitation chamber to excite the treatment gas before the treatment gas being dispensed on the active process region portion of the substrate surface.

15. A method of treatment a substrate surface, comprising:
moving a proximity head for surface treatment above a substrate, wherein the proximity head has at least one gas channel configured to dispense a treatment gas on a region of the substrate surface, the proximity head having at least one vacuum channel used to vacuum excess treatment gas from a reaction volume underneath the proximity head, and the proximity head for surface treatment covering the region of the substrate surface;
exciting the treatment gas in an excitation chamber of the proximity head before the treatment gas is dispensed on the region of the substrate surface; and
dispensing the excited treatment gas on the region of the substrate surface to treat the substrate surface.

16. The method of claim 15, wherein the surface treatment is used to remove surface impurities prior to the deposition of a film on the substrate.

17. The method of claim 15, wherein the surface treatment is used to increase initial deposition sites for an ALD of a barrier layer for copper.

18. The method of claim 15, wherein the surface treatment is performed on a deposited liner layer to enhance nucleation for an electroless copper seed layer to be deposited, or to remove contaminants on the deposited liner layer prior to the deposition of a copper seed layer.

19. The method of claim 17, wherein the metals in the barrier layer is selected from the group consisting of tantalum (Ta), titanium (Ti), tungsten (W), zirconium (Zr), hafnium (Hf), molybdenum (Mo), niobium (Nb), vanadium (V), ruthenium (Ru) and chromium (Cr).

20. The method of claim 18, wherein the metals in the deposited liner layer is selected from the group consisting of tantalum (Ta), titanium (Ti), tungsten (W), zirconium (Zr), hafnium (Hf), molybdenum (Mo), niobium (Nb), vanadium (V), ruthenium (Ru) and chromium (Cr).

21. The method of claim 15, wherein the treatment gas is excited by a hot-filament, by laser, by ultra-violent (UV), or by plasma.
